(19) United States
(12) Patent Application Publication
(10) Pub. No.: US 2014/0209931 A1
(43) Pub. Date: Jul. 31, 2014

(54) LED BOARD STRUCTURE AND METHOD OF MANUFACTURING SAME

(71) Applicant: Hsu-Wen LIAO, Pingjhen City (TW)

(72) Inventor: Hsu-Wen LIAO, Pingjhen City (TW)

(21) Appl. No.: 13/768,703

(22) Filed: Feb. 15, 2013

(30) Foreign Application Priority Data
Jan. 25, 2013 (TW) 102102794

(51) Int. Cl. H01L 33/50

(52) U.S. Cl. CPC H01L 33/507; H01L 33/50
USPC 257/88; 438/27

(57) ABSTRACT

An LED board structure includes a light-pervious substrate having a plurality of light-pervious areas formed thereon, a plurality of patterned conductive traces arranged on the light-pervious substrate at locations other than the light-pervious areas, and a plurality of LEDs correspondingly arranged on the light-pervious areas and respectively having two electrode terminals electrically connected to the patterned conductive traces. With these arrangements, light emitted from the LEDs not only projects forward, but also backwardly passes through the light-pervious areas, so that both sides of the LED board structure are illuminated by the LEDs. A method of manufacturing an LED board structure is also disclosed.

### CROSS-REFERENCE TO RELATED APPLICATION

This application claims the priority benefit of Taiwan application serial no. 102102794, filed on Jan. 25, 2013. The entirety of the above-mentioned patent application is hereby incorporated by reference herein and made a part of this specification.

### TECHNICAL FIELD

The technical filed relates to an LED board structure and method of manufacturing same, and more particularly to an LED board structure enabling double-sided illumination and method of manufacturing same.

### BACKGROUND

A light-emitting diode (LED) is a highly power-saving illuminating element providing long service life, and it is environmentally friendly because it does not contain any hazardous metal that would cause pollution to the ambient environment. Currently, LED lights have widely replaced the conventional power-saving bulbs, fluorescent tubes, incandescent bulbs and other types of fluorescent lamps to serve as a very popular light source in people's daily life.

To be compatible with the lamp holders for the conventional lighting bulbs or tubes, most of the currently available LED lights are manufactured to have forms the same as the conventional lighting bulbs or tubes. However, the bulb-shaped or the tube-shaped LED lights are not suitable for use in some specific items, such as advertisement signboards, indicator boards and the like. Instead, customized LED lights can provide higher lighting efficiency in these specific items.

Generally, the LED lights includes an opaque substrate, on which a plurality of LEDs is arranged, and light emitted from the LEDs can only be projected in a specific direction. For the light emitted from the LEDs to project in different directions, such as in two opposite directions, it is necessary to arrange the LEDs on both front and rear sides of the substrate. This technique has been disclosed in Taiwan Invention Patent Publication No. 511299 entitled “Metal substrate with double LED for double side light emission”. In the disclosure of Taiwan Invention Patent Number I351549 entitled “Double-sided liquid crystal display device”, a plurality of LED light sources is introduced into a light guide plate from a lateral side thereof, and a reflector in the light guide plate reflects the light emitted by the LED light sources to provide double-sided illumination. Further, in the disclosure of Taiwan New Utility Model Patent Number M332942 entitled “LED with bi-directional shining and heat-radiation”, a substrate is provided with a through hole, in which an LED is arranged; and a lens is provided to enclose the LED therein, so that a double-sided illumination effect can be achieved with one single LED. However, the provision of a through hole on the substrate as well as the mounting of the LED in the through hole require a high-precision packaging technique and involves in a considerably complicated manufacturing process.

### SUMMARY

An exemplary embodiment provides an LED board structure, which includes a light-pervious substrate having light-pervious areas formed thereon, a plurality of patterned conductive traces arranged on the light-pervious substrate at locations other than the light-pervious areas, and a plurality of LEDs correspondingly arranged in the light-pervious areas with two electrode terminals of each LED electrically connected to the patterned conductive traces. With these arrangements, light emitted from the LEDs not only projects forward, but also backwardly passes through the light-pervious areas, so that both sides of the LED board structure are illuminated by the LEDs.

An exemplary embodiment provides a method of manufacturing an LED board structure. The method includes the steps of preparing a light-pervious substrate having at least one light-pervious area formed thereon; arranging at least one patterned conductive trace on the light-pervious substrate at a location other than the light-pervious area; arranging at least one LED on the light-pervious substrate at a location corresponding to the light-pervious area; and electrically connecting two electrode terminals of each LED to the patterned conductive trace.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a plan view of an LED board structure according to a first exemplary embodiment of the disclosure, in which multiple LEDs are connected in series;

FIG. 2 is a side view of FIG. 1;

FIG. 3 is a plan view of an LED board structure according to a second exemplary embodiment of the disclosure, in which multiple LEDs are connected in parallel in one manner;

FIG. 4 is a plan view of an LED board structure according to a third exemplary embodiment, in which multiple LEDs are connected in parallel in another manner;

FIG. 5 is a side view of an LED board structure according to a fourth exemplary embodiment of the disclosure, in which a fluorescent layer is coated on one side of a light-pervious substrate thereof;

FIGS. 6A to 6C show the fluorescent layer of FIG. 5 can be coated on the substrate in different shapes;

FIG. 7 is a side view of an LED board structure according to a fifth exemplary embodiment of the disclosure, of which the LEDs are protectively encapsulated;

FIG. 8 is a side view of an LED board structure according to a sixth exemplary embodiment of the disclosure, of which the LEDs are alternately arranged on two opposite sides of the substrate; and

FIG. 9 is a flowchart showing the steps included in a method of manufacturing an LED board structure enabling double-sided illumination according to the disclosure.

### DETAILED DESCRIPTION OF DISCLOSED EMBODIMENTS

T Reference will now be made in detail to the exemplary embodiments of the disclosure, examples of which are illustrated in the accompanying drawings. Wherever possible, the same reference numbers are used in the drawings and the description to refer to the same or like parts

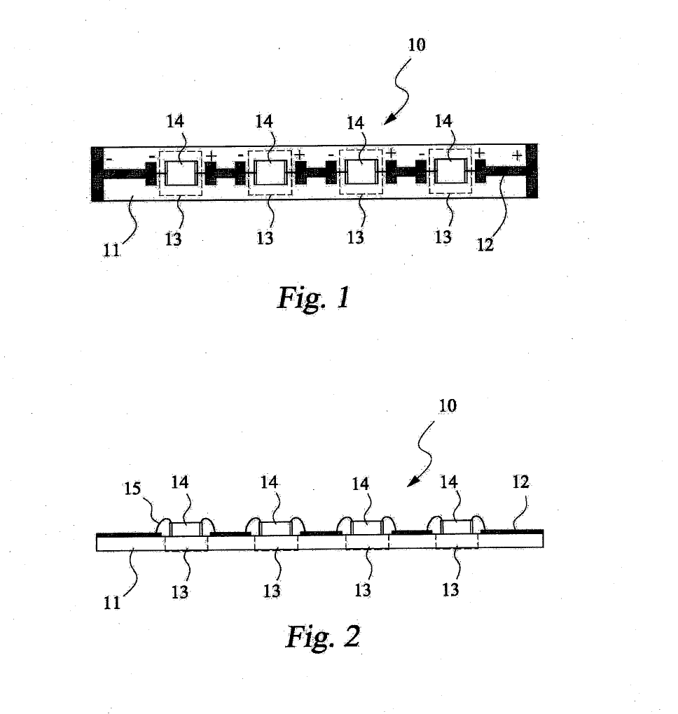

Please refer to FIG. 1, which is a plan view of an LED board structure 10 according to a first embodiment of the disclosure that enables double-sided illumination, and to FIG. 2 that is a side view of FIG. 1. For the purpose of conciseness and clarity, the disclosure is also briefly referred to as the LED board structure herein. As shown, in the first embodiment, the LED board structure 10 includes a light-pervious substrate 11 in the form of a flat plate. The light-pervious substrate 11 is made of a light-pervious material, including but not limited to a glass material, a plastic material, a resin material, a silicone material, a ceramic material, or any other suitable material. Alternatively, the light-pervious substrate 11 can be made of a flexible material, such as any PE-series plastic material, polymethylmethacrylate (PMMA), polycarbonate (PC), or polyimide (PI). However, it is understood the light-pervious substrate 11 according to the disclosure is not necessarily limited to the above-listed materials.

As can be seen in FIG. 1, on one of two opposite sides of the light-pervious substrate 11, there are provided a plurality of spaced patterned conductive traces 12. These patterned conductive traces 12 are respectively a substantially lying I-shaped conductive trace 12, and are sequentially arranged in one row, such that an area of the light-pervious substrate 11 between any two adjacent I-shaped conductive traces 12 forms a light-pervious area 13. On each of the light-pervious areas 13, an LED 14 is arranged. Each LED 14 has two electrode terminals that are electrically connected to two I-shaped conductive traces 12 immediately located at two opposite lateral sides of the LED 14. In another operable embodiment of the disclosure, the patterned conductive traces 12, the light-pervious areas 13 and the LEDs 14 can be arranged in multiple rows to form an array on the light-pervious substrate 11. However, in the disclosure, there is not particular limit to the number of rows or the shape of the array.

In the first embodiment shown in FIGS. 1 and 2, each LED 14 is connected at a positive terminal thereof to a negative terminal of a preceding LED 14. Correspondingly, each LED 14 is connected at a negative terminal thereof to a positive terminal of a following LED 14. In this manner, all the LEDs 14 are connected in series to one another. According to the disclosure, the two electrode terminals of each LED 14 can be connected to the patterned conductive traces 12 via wires 15 by way of wire bonding or be directly welded to the patterned conductive traces 12 by way of spot welding. However, it is understood, in the disclosure, the electrode terminals of the LEDs 14 can be connected to the patterned conductive traces 12 in other suitable ways without being limited to the above-mentioned ways.

In the first embodiment shown in FIGS. 1 and 2, the first LED 14 on the substrate 11 (i.e. the rightmost LED 14 in the drawing) is connected to a positive potential of a power supply (not shown). Correspondingly, the last LED 14 on the substrate 11 (i.e. the leftmost LED 14 in the drawing) is connected to a negative potential of the power supply. Thus, when electric power is supplied from the power supply to the LEDs 14 for the latter to emit light, the emitted light not only projects forward, but also backward passes through the light-pervious areas 13 on the substrate 11, so that the LED board structure 10 enables double-sided illumination.

In summary, in the first embodiment of the disclosure, the LED board structure 10 includes a light-pervious substrate 11 having a plurality of light-pervious areas 13 formed thereon, a plurality of patterned conductive traces 12 formed on one of two opposite sides of the substrate 11 at locations other than the light-pervious areas 13, and a plurality of LEDs 14 correspondingly arranged on the light-pervious areas 13, so that light emitted from the LEDs 14 not only projects forward, but also backward passes through the light-pervious areas 13 to enable illumination on both sides of the LED board structure 10.

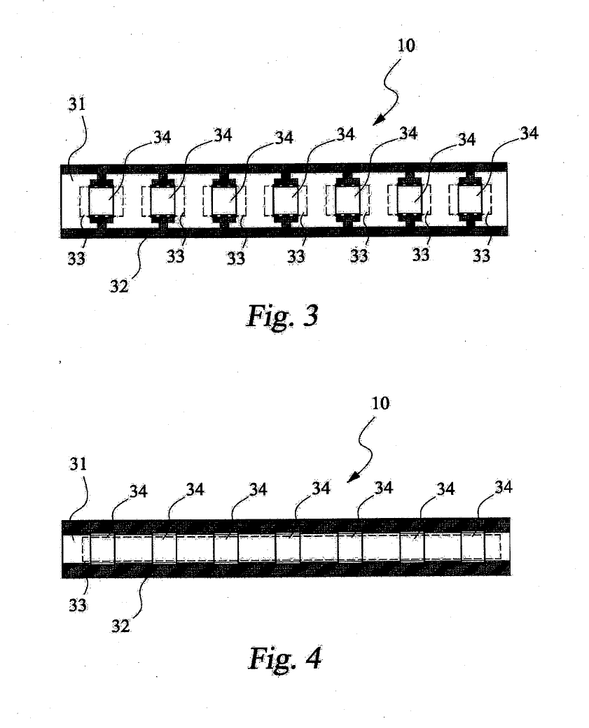

In the first embodiment, the LEDs 14 on the substrate 11 are connected in series to one another. However, in a second embodiment of the disclosure as shown in FIG. 3, there is a light-pervious substrate 31, on which two patterned conductive traces 32 are arranged as two parallelly spaced strips. In other operable embodiments, an even number of patterned conductive traces more than two, such as four, six and so on, can be parallelly spaced on the substrate. That is, according to the disclosure, the patterned conductive traces are not particularly limited in number.

In the second embodiment as shown in FIG. 3, the two parallelly spaced patterned conductive traces 32 respectively include multiple substantially T-shaped portions, which are correspondingly inwardly extended from the two parallelly spaced patterned conductive traces 32 in pairs, and a light-pervious area 33 is formed on the substrate 31 between each pair of two facing T-shaped portions of the patterned conductive traces 32. Again, an LED 34 is arranged on each of the light-pervious areas 33. In a third embodiment as shown in FIG. 4, the two patterned conductive traces 32 do not have the T-shaped portions, and a long strip of light-pervious area 33 is formed on the substrate 31 between the two parallelly spaced patterned conductive traces 32 with a row of spaced LEDs 34 arranged in the light-pervious area 33.

In the second and third embodiments shown in FIGS. 3 and 4, respectively, the two parallelly spaced patterned conductive traces 32 are connected to the two electrode terminals of each LED 34. For example, the upper patterned conductive trace 32 shown in each of FIGS. 3 and 4 is connected to the positive terminals of the LEDs 34 while the lower patterned conductive trace 32 is connected to the negative terminals of the LEDs 34, so that the LEDs 34 are connected in parallel to one another. The upper patterned conductive trace 32 is also connected to a positive terminal of a power supply (not shown) while the lower patterned conductive trace 32 is connected to a negative terminal of the power supply, so that electric power can be supplied from the power supply for driving the LEDs 34 to emit light.

Just as the first embodiment shown in FIGS. 1 and 2, in the second and third embodiments, the LEDs 34 can be connected to the patterned conductive traces 32 via wires by way of wire bonding or be directly welded to the patterned conductive traces 32 by way of spot welding without being limited to a particular manner. This principle is applicable to all other embodiments of the disclosure described herein.

In another operable embodiment of the disclosure not shown herein, the LEDs are arranged in an array. These LEDs can be connected in series, in parallel, or in both series and parallel, mainly depending on the voltage and current of the power supply, so as to get the best possible power factor.

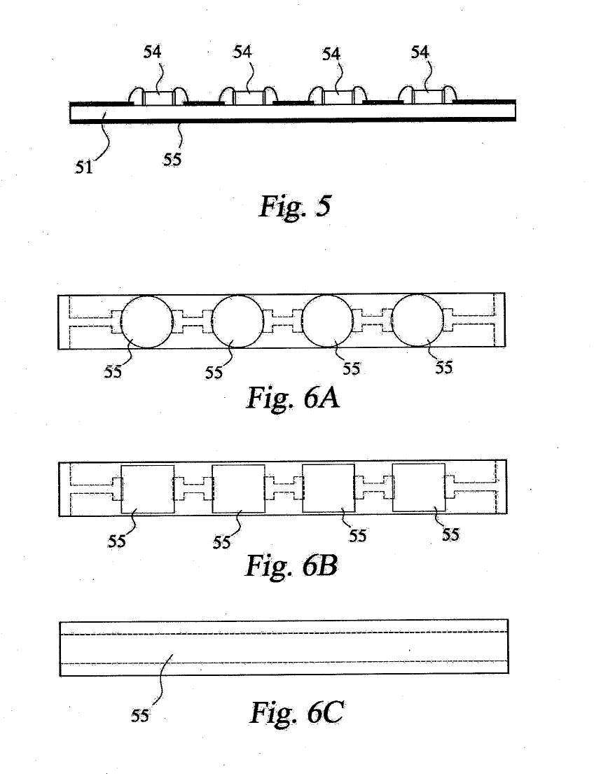

To get enhanced LED lighting efficiency, a fourth embodiment of the disclosure as shown in FIG. 5 further includes a fluorescent layer. As can be seen in FIG. 5, the fourth embodiment includes a light-pervious substrate 51 having a plurality of LEDs 54 arranged on one of two opposite side thereof and at least one fluorescent layer 55 formed on the other side thereof opposite to the LEDs 54. The fluorescent layer 55 is formed by coating fluorescent powder on the other surface of the substrate 51. The fluorescent powder in the fluorescent layer 55 is helpful in increasing the lighting efficiency of the LEDs 54 when the light emitted therefrom backward passes through the substrate 51.

In the fourth embodiment, the fluorescent layer 55 is provided on the substrate 51 at one or multiple locations corresponding to the light-pervious area or areas. Please refer to FIGS. 6A to 6C. The fluorescent layer 55 can be formed on the substrate 51 in different shapes corresponding to those of the light-pervious areas, such as in a round shape as shown in FIG. 6A, in an oval shape (not shown), in a square shape as shown in FIG. 6B, in a rectangular shape as shown in FIG. 6C, or in any other polygonal shape. However, it is understood the fluorescent layer in the disclosure is not limited to the above-mentioned shapes.

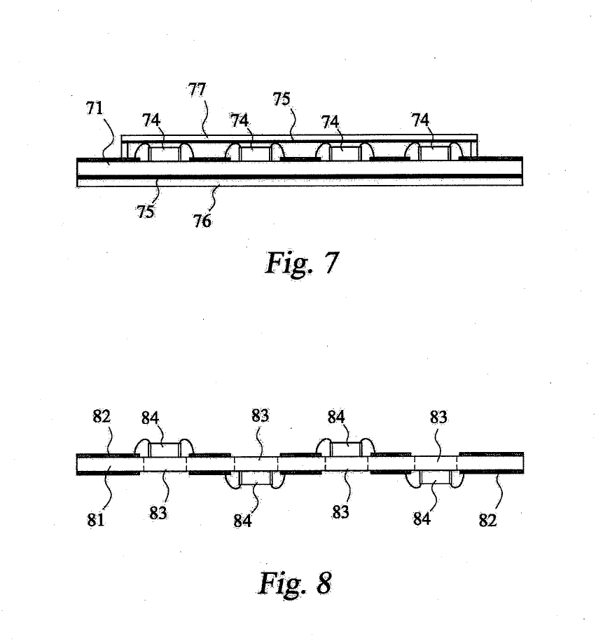

FIG. 7 is a side view of an LED board structure according to a fifth embodiment of the disclosure, of which the LEDs are protectively encapsulated. As can be seen in FIG. 7, the fifth embodiment includes a light-pervious substrate 71, on one side of which a plurality of LEDs 74 is arranged and on the other side of which a fluorescent layer 75 is formed. The fifth embodiment is characterized in that a first light-pervious plate 76 is further provided on an outer side of the fluorescent layer 75 to protectively cover the latter, and a second light-pervious plate 77 is further provided atop the LEDs 74 to protectively encapsulate the latter therein. To enhance the lighting efficiency of the LEDs 74 in the fifth embodiment, fluorescent powder can be coated on an inner side of the second light-pervious plate 77 facing toward the LEDs 74 to form at least one additional fluorescent layer 75. As in the fourth embodiment, the fluorescent layers 75 in the fifth embodiment can be arranged at one or multiple locations corresponding to the LED or LEDs 74 and in a shape corresponding to that of the LEDs 74, such as any one of those shown in FIGS. 6A to 6C. However, it is understood the fluorescent layers 75 in the disclosure are not limited to the shapes illustrated in FIGS. 6A to 6C.

FIG. 8 is a side view of an LED board structure according to a sixth embodiment of the disclosure, of which the LEDs are alternately arranged on two opposite sides of the substrate. As can be seen in FIG. 8, the sixth embodiment includes a light-pervious substrate 81 having patterned conductive traces 82 formed on both sides thereof. The patterned conductive traces 82 on the two sides of the substrate 81 can be symmetrical or asymmetrical in location and can be arranged in rows or in an array, similar to those described with FIGS. 1 and 3. The substrate 81 also has multiple light-pervious areas 83 formed thereon, and the patterned conductive traces 82 are arranged on the substrate 81 at locations other than the light-pervious areas 83. Multiple LEDs 84 are correspondingly arranged on the light-pervious areas 83 with two electrode terminals of every LED 84 being connected to the patterned conductive traces 82, such that the LEDs 84 are connected in series or in parallel to one another, as those described with FIGS. 1 and 3.

It is noted that, in the sixth embodiment as shown in FIG. 8, the LEDs 84 are arranged on both sides of the substrate 81, and the LEDs 84 on one side of the substrate 81 are spaced alternately with the LEDs 84 on the other side of the substrate 81. In other words, the patterned conductive traces 82 and the LEDs 84 in each row on two sides of the substrate 81 are staggered relative to one another. For instance, any two adjacent rows of LEDs on a first side of the substrate are spaced from one another by a distance at least equal to a width of one LED, and the rows of LEDs arranged on an opposite second side of the substrate are located corresponding to the spaces between any two adjacent rows of LEDs on the first side of the substrate. In another operable embodiment, the LEDs can be grouped on the first side of the substrate to form multiple LED arrays with any two adjacent LED arrays spaced from each other by a distance at least equal to a width of one LED array, and the LEDs arranged on the opposite second side of the substrate are also grouped into multiple LED arrays that are located corresponding to the spaces between any two adjacent LED arrays on the first side of the substrate.

In the sixth embodiment shown in FIG. 8, the LEDs 84 located at two opposite sides of the substrate 81 can also be protectively encapsulated in two second light-pervious plates as that provided in the fifth embodiment shown in FIG. 7. Further, the two second light-pervious plates can also respectively have at least one fluorescent layer coated on an inner side thereof to enhance the lighting efficiency of the LEDs 84, just like the fifth embodiment.

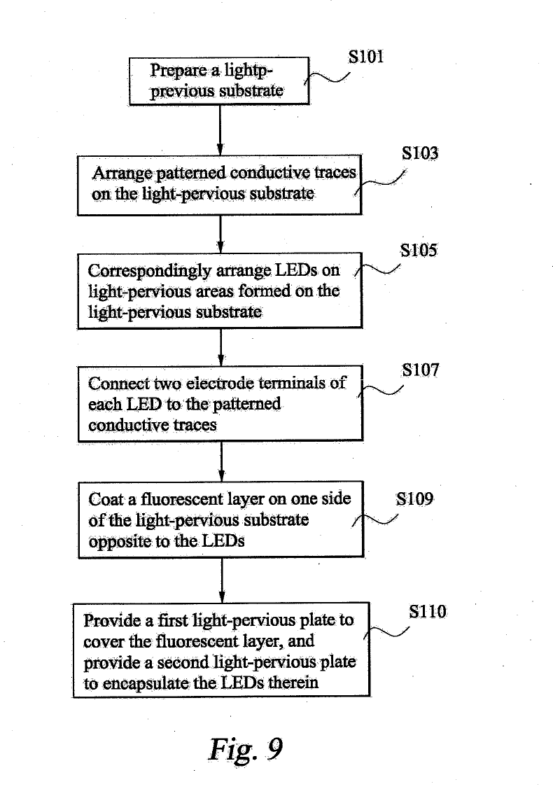

FIG. 9 is a flowchart showing the steps included in a method of manufacturing an LED board structure enabling double-sided illumination according to the disclosure. As shown, in the first step S101 of the method of the disclosure, a light-pervious substrate is prepared, and the light-pervious substrate has a plurality of light-pervious areas formed thereon. Then, in the second step S103, multiple patterned conductive traces are provided on the light-pervious substrate at locations other than the light-pervious areas. The patterned conductive traces can be formed on the light-pervious substrate by way of printing or electroplating. Of course, the disclosure is not limited to the above described manners, and there are still other acceptable ways for forming the patterned conductive traces on the substrate.

In the third step S105, a plurality of LEDs is arranged on one side of the light-pervious substrate at locations corresponding to the light-pervious areas. Then, in the fourth step S107, the LEDs are connected at respective two electrode terminals to the patterned conductive traces, so that the LEDs are connected in series or in parallel to one another.

In the fifth step S109, fluorescent powder is coated on another side of the light-pervious substrate opposite to the LEDs to form at least one fluorescent layer. More particularly, the at least one fluorescent layer can be formed on the other side of the substrate only at locations corresponding to the light-pervious areas. Then, in the final step S110, a first light-pervious plate is provided to cover the fluorescent layer, and a second light-pervious plate is provided to protectively encapsulate the LEDs therein. An additional fluorescent layer can be coated on an inner side of the second light-pervious plate facing toward the LEDs. Similarly, the additional fluorescent layer can be formed on the inner side of the second light-pervious plate only at locations corresponding to the light-pervious areas.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An LED board structure, comprising:
a light-pervious substrate having at least one light-pervious area formed thereon;
at least one patterned conductive trace being arranged on the light-pervious substrate at a location other than the at least one light-pervious area; and
at least one LED being correspondingly arranged on the at least one light-pervious area; and each LED having two electrode terminals connected to the at least one patterned conductive trace;
whereby light emitted from the at least one LED not only projects forward, but also backwardly passes through the light-pervious area, so that both sides of the LED board structure are illuminated by the at least one LED.

2. The LED board structure as claimed in claim 1, wherein the light-pervious substrate is made of a light-pervious material selected from the group consisting of a glass material, a plastic material, a resin material, a silicone material, and a ceramic material.

3. The LED board structure as claimed in claim 1, wherein the light-pervious substrate is made of a flexible material selected from the group consisting of any PE-series plastic material, polymethylmethacrylate (PMMA), polycarbonate (PC), or polyimide (PI).

4. The LED board structure as claimed in claim 1, wherein the light-pervious area is in the form of a long strip, in which a row of LEDs is arranged.

5. The LED board structure as claimed in claim 1, wherein the at least one patterned conductive trace and the at least one LED are arranged on one of two opposite sides of the light-pervious substrate.

6. The LED board structure as claimed in claim 1, wherein the at least one patterned conductive trace and the at least one LED are arranged on both of two opposite sides of the light-pervious substrate, and the patterned conductive trace and the LED arranged on one side of the substrate are staggered relative to the patterned conductive trace and the LED arranged on the other side of the substrate.

7. The LED board structure as claimed in claim 6, wherein there are multiple LEDs and multiple patterned conductive traces arranged on both sides of the substrate in at least one row or in at least one array.

8. The LED board structure enabling double-sided illumination as claimed in claim 1, further comprising at least one fluorescent layer formed by coating fluorescent powder on one side of the light-pervious substrate opposite to the at least one LED.

9. The LED board structure as claimed in claim 8, wherein the fluorescent layer is formed on one side of the light-pervious substrate at a location corresponding to the at least one light-pervious area.

10. The LED board structure enabling double-sided illumination as claimed in claim 8, further comprising a first light-pervious plate for covering an outer side of the fluorescent layer.

11. The LED board structure as claimed in claim 1, further comprising a second light-pervious plate for protectively encapsulating the at least one LED arranged on the light-pervious substrate.

12. The LED board structure as claimed in claim 11, wherein the second light-pervious plate has at least one fluorescent layer coated on an inner side thereof facing toward the at least one LED.

13. The LED board structure as claimed in claim 12, wherein the at least one fluorescent layer is formed on the inner side of the second light-pervious plate only at a location corresponding to the at least one LED.

14. The LED board structure as claimed in claim 1, wherein the two electrode terminals of each LED are connected to the at least one patterned conductive trace by way of spot welding.

15. The LED board structure as claimed in claim 1, wherein the two electrode terminals of each LED are connected to the at least one patterned conductive trace via two wires by way of wire bonding.

16. A method of manufacturing LED board structure, comprising the following steps:
preparing a light-pervious substrate, on which at least one light-pervious area is formed;
arranging at least one patterned conductive trace on the light-pervious substrate at a location other than the at least one light-pervious area;
arranging a plurality of LEDs on the light-pervious substrate at locations corresponding to the at least light-pervious area; and
electrically connecting two electrode terminals of each of the LEDs to the at least one patterned conductive trace, so that the LEDs are connected in series or in parallel to one another.

17. The method of manufacturing LED board structure as claimed in claim 16, wherein the light-pervious substrate is made of a light-pervious material selected from the group consisting of a glass material, a plastic material, a resin material, a silicone material, and a ceramic material.

18. The method of manufacturing LED board structure as claimed in claim 16, wherein the light-pervious substrate is made of a flexible material selected from the group consisting of any PE-series plastic material, polymethylmethacrylate (PMMA), polycarbonate (PC), or polyimide (PI).

19. The method of manufacturing LED board structure as claimed in claim 16, wherein the LEDs are arranged on the light-pervious substrate in at least one row or in at least one array.

20. The method of manufacturing LED board structure as claimed in claim 16, wherein there are multiple light-pervious areas formed on the light-pervious substrate, and each of the light-pervious areas has at least one of the LEDs correspondingly arranged therein.

21. The method of manufacturing LED board structure as claimed in claim 16, further comprising the following step after the step of preparing the light-pervious substrate: coating at least one fluorescent layer on one side of the light-pervious substrate opposite to the LEDs.

22. The method of manufacturing LED board structure as claimed in claim 21, wherein the fluorescent layer is coated on one side of the light-pervious substrate at a location corresponding to the at least one light-pervious area.

23. The method of manufacturing LED board structure as claimed in claim 21, further comprising the following step: providing a first light-pervious plate on an outer side of the fluorescent layer to cover the latter.

24. The method of manufacturing LED board structure as claimed in claim 16, further comprising the following step after the step of electrically connecting the two electrode terminals of each of the LEDs to the patterned conductive trace: providing at least one second light-pervious plate to encapsulate the LEDs arranged on the light-pervious substrate.

25. The method of manufacturing LED board structure as claimed in claim 24, further comprising the following step: coating at least one fluorescent layer on an inner side of the at least one second light-pervious plate facing toward the LEDs.

26. The method of manufacturing LED board structure as claimed in claim 25, wherein the at least one fluorescent layer is coated on the inner side of the at least one second light-pervious plate only at a location corresponding to the at least one light-pervious area.

27. The method of manufacturing LED board structure as claimed in claim 16, wherein, in the step of electrically connecting the two electrode terminals of each of the LEDs to the patterned conductive trace, the electrode terminals of the LEDs are welded to the patterned conductive trace.

28. The method of manufacturing LED board structure as claimed in claim 16, wherein, in the step of electrically connecting the two electrode terminals of each of the LEDs to the patterned conductive trace, the electrode terminals of the LEDs are connected to the patterned conductive trace via wires by way of wire bonding.
